(19) United States
(12) Patent Application Publication
(10) Pub. No.: US 2015/0136734 A1
(43) Pub. Date: May 21, 2015

(54) Substrate Treating Apparatus and Method

(71) Applicant: PSK Inc., Gyeonggi-do (KR)

(72) Inventors: Hee Sun Chae, Gyeonggi-do (KR); Jeong Hee Cho, Gyeonggi-do (KR); Jong Sik Lee, Gyeonggi-do (KR); Han Saem Rhee, Gyeonggi-do (KR); Hyun Jun Kim, Gyeonggi-do (KR)

(21) Appl. No.: 14/541,310

(22) Filed: Nov. 14, 2014

(30) Foreign Application Priority Data
Nov. 15, 2013 (KR) 10-2013-0139201

(51) Int. Cl. H01J 37/32

(52) U.S. Cl. CPC H01J 37/32449; H01J 37/32458; H01J 37/3211; H01J 2237/334; H01J 2237/0656
USPC 216/67; 156/345.38; 156/345.33

(57) ABSTRACT

Provided is a substrate treating apparatus including a first supplying unit, a second supplying unit, a first source, a second source, a gas separation member or the like. Plasma generated from a first gas supplied from a first supplying unit by the first source is used for treating a central area of a substrate. Plasma generated from a second gas supplied from a second supplying unit by the second source is used for treating an edge area of the substrate. A gas separation member prevents plasmas generated respectively from first and second gases from being mixed up.

### CROSS-REFERENCE TO RELATED APPLICATIONS

This U.S. non-provisional patent application claims priority under 35 U.S.C. §119 of Korean Patent Application No. 10-2013-0139201, filed on Nov. 15, 2013, the entire contents of which are hereby incorporated by reference.

### BACKGROUND OF THE INVENTION

The present invention disclosed herein relates to a substrate treating apparatus and method, and more particularly, to a substrate treating apparatus and method using plasma.

Manufacturing a semiconductor element requires various processes such as deposition, photolithography, etching, ashing, cleaning, and polishing. Many processes such as deposition, etching, and ashing use plasma to process a semiconductor substrate such as a wafer.

In general, a substrate treating apparatus using plasma allows a gas injected into a plasma generator through a gas supplying member to be spread throughout the generator to generate plasma. The plasma generated from the plasma generator is supplied to a processing chamber in which a substrate treating process is performed. The plasma supplied to the processing chamber is supplied to a substrate surface through a baffle in the processing chamber. This causes plasma to be non-uniformly supplied between central and edge areas of the substrate. Therefore, this results in non-uniformity of substrate treating processes such as ashing and etching.

### SUMMARY OF THE INVENTION

The present invention provides a substrate treating apparatus and a substrate treating method, capable of adjusting a plasma density during a substrate treating process using plasma.

The object of the present invention is not limited to the aforesaid, but other objects not described herein will be clearly understood by those skilled in the art from descriptions below.

Embodiments of the present invention provide substrate treating apparatuses including: a chamber including a lower housing and an upper housing provided on the lower housing; a gas supplying unit supplying a gas to the chamber; a plasma source generating plasma from the gas; and a substrate supporting unit disposed in the lower housing to support a substrate, wherein an opening is formed between the upper housing and the lower housing such that an inner space of the lower housing and an inner space of the upper housing are communicated with each other, wherein the gas supplying unit includes a first supplying unit supplying a gas into the upper housing, and a second supplying unit supplying a gas directly into the lower housing, and wherein the plasma source includes a first source generating plasma from the gas supplied into the upper housing, and a second source generating plasma from the gas supplied into the lower housing.

In some embodiments, the opening may be disposed to face a central area of the substrate positioned on the substrate supporting unit.

In other embodiments, the second supplying unit may be disposed around the opening, and may be provided to supply a gas to an area facing an edge area of the substrate in the inner space of the lower housing.

In still other embodiments, the first source may wind a side surface of the upper housing.

In even other embodiments, the second source may wind a side surface of the lower housing.

In yet other embodiments, the second source may be disposed over the lower housing.

In further embodiments, the lower housing may have a vortex forming surface on an inner side thereof.

In still further embodiments, substrate treating apparatus may further include a gas separation member separating a first space from a second space, the first space facing the central area of the substrate in the inner space of the lower housing and the second space facing the edge area of the substrate, wherein the gas separation member may be disposed between first and second spaces and has an inner space with opened upper and lower ends.

In even further embodiments, the gas separation member may have a vortex forming surface.

In other embodiments of the present invention, the substrate treating methods include: treating the central area of the substrate using plasma generated by the first source from the first gas supplied from the first supplying unit; and treating the edge area of the substrate using plasma generated by the second source from the second gas supplied from the second supplying unit.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of a substrate treating apparatus according to an embodiment of the present invention;

FIG. 2 is a cut-away perspective view illustrating a portion of a second gas distribution plate in FIG. 1;

FIG. 3 is a cross-sectional view of a substrate treating apparatus in FIG. 1 including a baffle;

FIG. 4 is a cross-sectional view illustrating a substrate treating apparatus in which a second source in FIG. 1 is provided over a lower housing;

FIG. 5 is a cross-sectional view illustrating a vortex forming surface provided on inner and outer surfaces of a gas separation member in FIG. 1;

FIG. 6 is a cross-sectional view illustrating a vortex forming surface provided on the outer surface of the gas separation member in FIG. 1;

FIG. 7 is a cross-sectional view illustrating a vortex forming surface provided on the inner surface of the gas separation member in FIG. 1;

FIG. 8 is a cross-sectional view illustrating a vortex forming surface provided on an inner surface of the lower housing in FIG. 1;

FIG. 9 is a cross-sectional view illustrating a substrate treating apparatus in which the gas separation member in FIG. 1 is provided to have the shape of, a truncated cone of which a diameter gradually increases from top to bottom; and

FIG. 10 is a cross-sectional view illustrating a substrate treating apparatus in which the gas separation member in FIG. 1 is provided to have the shape of a truncated cone of which a diameter gradually decreases from top to bottom.

### DETAILED DESCRIPTION OF PREFERRED EMBODIMENTS

Hereinafter, preferred embodiments of the present invention will be described below in more detail with reference to the accompanying drawings. The embodiments of the present invention may, however, be embodied in different forms and should not be construed as limited to the embodiments set forth herein. These embodiments are provided so that this disclosure will be thorough and complete, and will fully convey the concept of the present invention to those skilled in the art. Therefore, shapes of the elements illustrated in the figures are exaggerated for clarity.

A substrate 10 in an embodiment of the present invention may be a semiconductor wafer, but is not limited thereto. Thus, the substrate 10 may be a different kind of substrate such as a glass substrate.

Also, in an embodiment of the present invention, a substrate treating apparatus may be an apparatus performing a process such as ashing, deposition, or etching using plasma.

A substrate treating apparatus according to an embodiment of the present invention may adjust each of plasma generation rates for treating central and edge areas of the substrate during a substrate treating process. Accordingly, the substrate treating apparatus according to an embodiment of the present invention may provide a uniform plasma density over a whole area of the substrate 10 in a large-sized area process.

Hereinafter, a substrate treating apparatus 1 according to an embodiment of the present invention will be described.

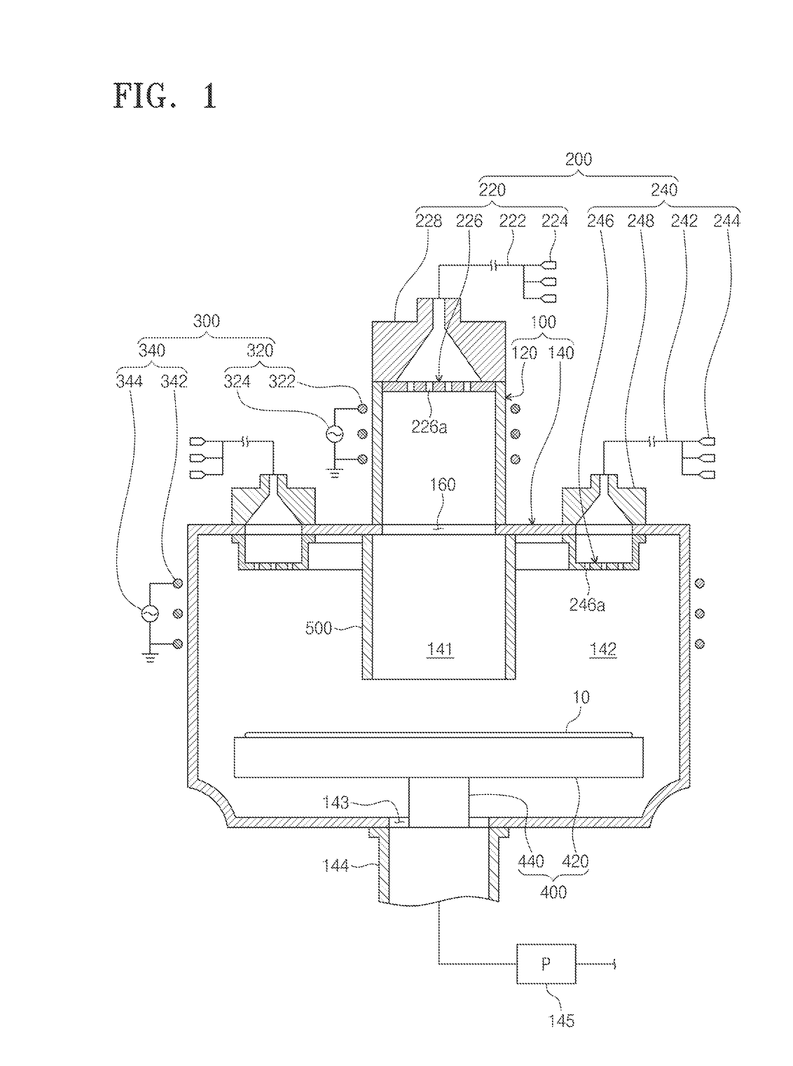

FIG. 1 is a cross-sectional view of a substrate treating apparatus 1 according to an embodiment of the present invention. Referring to FIG. 1, the substrate treating apparatus 1 includes a chamber 100, a gas supplying unit 200, a plasma source 300, a substrate supporting unit 400, and a gas separation member 500.

The chamber 100 includes an upper housing 120 and a lower housing 140. The gas supplying unit 200 includes a first supplying unit 220 and a second supplying unit 240. The plasma source 300 includes a first source 320 and a second source 340.

Hereinafter, a gas supplied from the first supplying unit 220 is called a first gas, and a gas supplied from the second supplying unit 240 is called a second gas.

Plasma generated from the first gas is used for treating a central area of the substrate 10. Plasma generated from the second gas is used for treating an edge area of the substrate 10. The first and second gases may be a single gas. In this case, the first and second gases may have the same or different kinds. The first and second gases may be a gas mixture. In this case, the first and second gases may have the same kind of gases, but may have different composition ratios. The first and second gases may have different supplying amounts. The first and second gases may include nitrogen (N₂), and oxygen (O₂) gases. Optionally, the first and second gases may further include other kinds of gases.

The chamber 100 provides a space for generating plasma from the gas supplied by the gas supplying unit 200. In addition, the chamber 100 provides a space for treating a substrate 10 by plasma.

The upper housing 120 has a space having opened upper and lower portions therein. The upper housing 120 may have a substantially cylindrical shape. The upper housing 120 is disposed on a lower housing 140 and coupled to the lower housing 140. The upper housing 120 provides a space for generating plasma from the first gas. A first supplying unit 220 is coupled to an upper portion of the upper housing 120.

The lower housing 140 has a first space 141 facing a central area of the substrate 10 and a second space 142 facing an edge area of the substrate 10 therein. The lower housing 140 may have a substantially cylindrical shape. An opening 160 is defined between the upper housing 120 and the lower housing 140 to communicate between an inner space of the upper housing 120 and an inner space of the lower housing 140. A sealing member (not shown) may be provided between the upper housing 120 and the lower housing 140 for sealing from the outside. A substrate loading hole (not shown) is defined in a sidewall of the lower housing 140. The substrate is loaded into and unloaded from the chamber 100 through the substrate loading hole (not shown). The substrate loading hole (not shown) may be opened and closed by an opening/closing member such as a door (not shown). An exhaust hole 143 is defined in a bottom surface of the lower housing 140. An exhaust line 144 is connected to the exhaust hole 143. A pump 145 is installed on the exhaust line 144. The pump 145 adjusts an inner pressure of the chamber 100 to a processing pressure. A residual gas and by-products in the chamber 100 are discharged to the outside of the chamber 100 through the exhaust line 144. The lower housing 140 provides a space for generating plasma from the second gas. The lower housing 140 provides a space for treating the substrate 10 by plasma. The second supplying unit 240 is coupled to an upper portion of the lower housing 140.

Plasma generated from the first gas in the upper housing 120 is supplied to the central area of the substrate 10 through the first space 141.

The second gas is excited to plasma in the second space 142. The plasma generated from the second gas is supplied to the edge area of the substrate 10 through the second space 142.

The first supplying unit 220 is provided above the upper housing 120. The first supplying unit 220 includes a first gas supplying line 222, a first gas storage 224, a first gas distribution plate 226, and a first gas port 228. The first supplying unit 220 may be provided singly or provided in plurality.

The first gas supplying line 222 is connected to the first gas port 228. The first gas supplied through the first gas port 228 flows into the upper housing 120 to be excited to plasma in the upper housing 120.

The first gas distribution plate 226 is disposed below the first gas port 228. The first gas distribution plate 226 maintains a density and flow of the first gas uniformly over a whole area in the upper housing 120 when the first gas is supplied to the upper housing 120. The first gas distribution plate 226 has a plate shape. The first gas distribution plate 226 has injection holes 226a extending from upper to lower ends thereof. The injection holes 226a may be formed with approximately the same density and diameter in each region of the first gas distribution plate 226.

The second supplying unit 240 is disposed around the opening 160. The second supplying unit 240 includes a second gas supplying line 242, a second gas storage 244, a second gas distribution plate 246, and a second gas port 248. The second supplying unit 240 may be provided singly or provided in plurality.

The second gas supplying line 242 is connected to the second gas port 248. The second gas supplied through the second gas port 248 flows into the second space 142 to be excited to plasma in the second space 142.

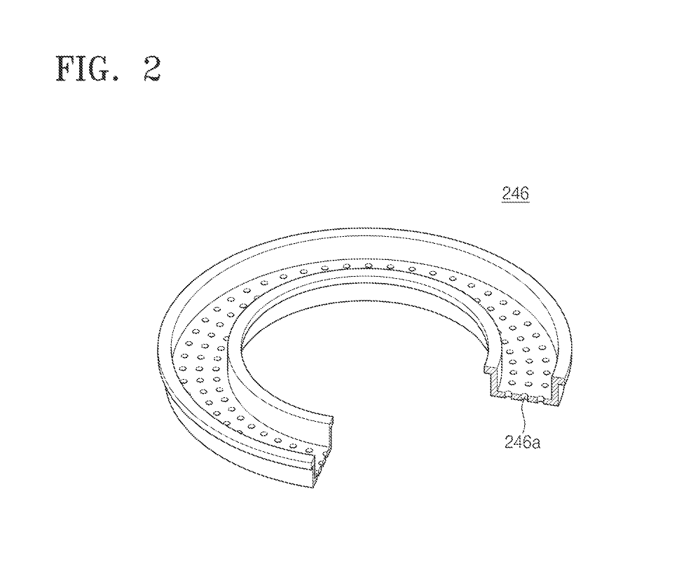

The second gas distribution plate 246 is disposed below the second gas port 248 of the second space 142. The second gas distribution plate 246 maintains a density and flow of the second gas uniformly over a whole area in the second space 142 when the second gas is supplied to the second space 142. The second gas distribution plate 246 is provided to surround the opening 160. Referring to FIG. 2, when viewed from the top, the second gas distribution plate 246 has an annular ring shape. The second gas distribution plate 246 has a longitudinal section which is U-shaped with a flat bottom. The second gas distribution plate 246 has a portion which is disposed on an upper portion thereof and protrude to the outside of a side surface, and thus may be easily coupled to a lower end of the second gas port 248. The second gas distribution plate 246 has injection holes 246a extending from upper to lower ends of the bottom surface thereof. The injection holes 246a may be formed with approximately the same density and diameter over the whole bottom surface.

Referring to FIG. 1 again, the first source 320 generates plasma from the first gas in the upper housing 120. The first source 320 may be an inductively coupled plasma source. The first source 320 includes a first antenna 322 and a first power supply 324. The first antenna 322 is provided outside the upper housing 120 so as to wind a side surface of the upper housing 120 several times. The first antenna 322 has one end coupled to a first power supply 324 and the other end coupled to the ground. The first power supply 324 applies power to the first antenna 322. The first power supply 324 may apply a high frequency power to the first antenna 322.

The second source 340 generates plasma from the second gas in the second space 142. The second source 340 may be an inductively coupled plasma source. The second source 340 includes a second antenna 342 and a second power supply 344. The second antenna 342 is provided outside the lower housing 140. The second antenna 342 may be provided to wind a side surface of the lower housing 140 several times. The second antenna 342 has one end coupled to the second power supply 344 and the other end coupled to the ground. The second power supply 344 applies power to the second antenna 342. The second power supply 344 may apply a high frequency power to the second antenna 342.

The substrate supporting unit 400 supports the substrate 10. The substrate supporting unit 400 includes a supporting plate 420 and a supporting shaft 440. The supporting plate 420 is disposed in the lower housing 140 and has a disc shape. The supporting plate 420 is supported by the supporting shaft 440. The substrate 10 is placed on the supporting plate 420. An electrode (not shown) may be provided in the supporting plate 420 and the substrate 10 may be supported by the supporting plate 420 through an electrostatic force.

The gas separation member 500 is disposed between first and second spaces 141 and 142. The gas separation member 500 separates first and second spaces 141 and 142 to prevent plasmas generated respectively from the upper housing 120 and the second space 142 from being mixed up. As plasmas of first and second spaces 141 and 142 are less mixed, it is easier to maintain the density, mixing ratio, distribution degree of the plasmas used for treating each of central and edge areas of the substrate 10 as those of processing conditions. The gas separation member 500 allows the second gas to flow closely to the second source 340, so as to increase a plasma generation rate by the second source 340. The gas separation member 500 has an inner space having opened upper and lower ends. The gas separation member 500 may have a cylindrical shape having the same diameter vertically. The gas separation member 500 has a top surface having an inner diameter equal to that of the opening 160. The gas separation member 500 is coupled to an undersurface of an upper portion of the lower housing 140 such that the center of the top surface of the gas separation member 500 corresponds to the center of the opening 160. The gas separation member 500 may be a material including a conductive or nonconductive material. The nonconductive material has a lower absorption rate of generated radical than that of the conductive material, so that a loss of generated plasma is low. The nonconductive material may include quartz, ceramic, and sapphire. Alternatively, the gas separation member 500 may not be provided.

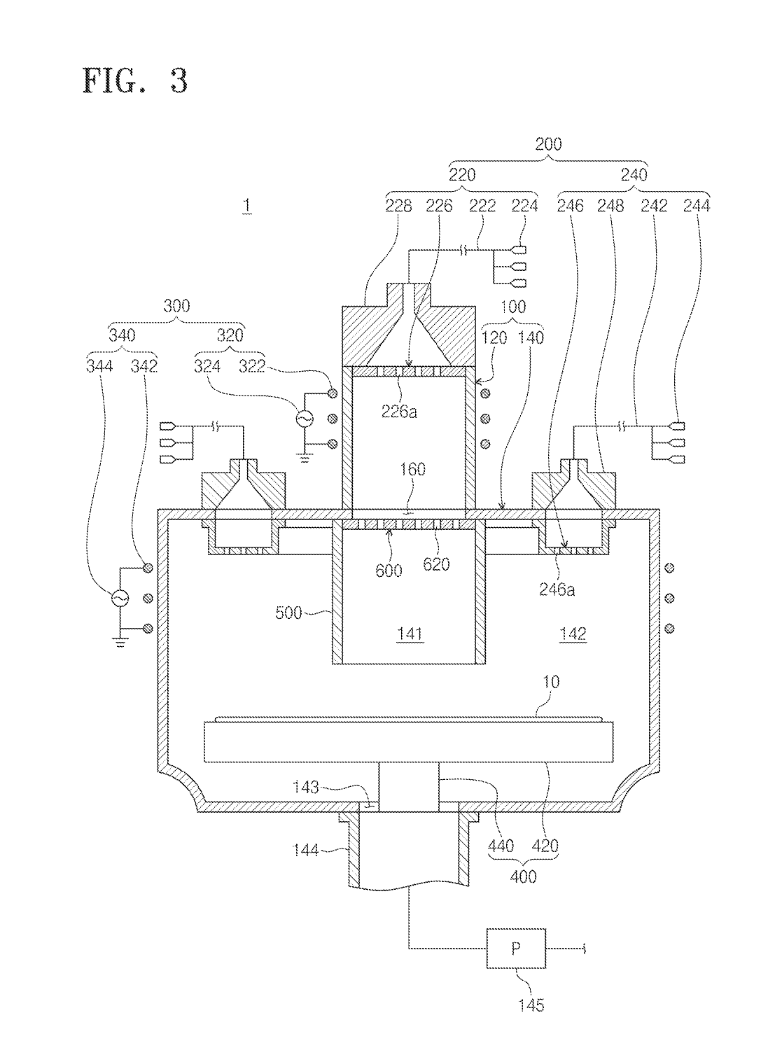

Referring to FIG. 3, the substrate treating apparatus 1 may further include a baffle 600 on a lower end of the opening 160. The baffle 600 has a disc shape. The baffle 600 has a diameter greater than that of the opening 160. The baffle 600 is connected to the ground. According to an embodiment, the baffle 600 is in contact with the chamber 100 and connected to the ground through the chamber 100. Alternatively, the baffle 600 may be directly connected to an additional ground line. The baffle 600 has injection holes 620 extending from upper to lower ends thereof. The injection holes 620 may be formed with approximately the same density and diameter in each region of the baffle 600. Alternatively, the injection holes 620 may be formed with a different density in each region of the baffle 600. Also, the injection holes 620 may be formed with a different diameter in each region of the baffle 600. Plasma is supplied from the upper housing 120 to the first space 141 through injection holes 620.

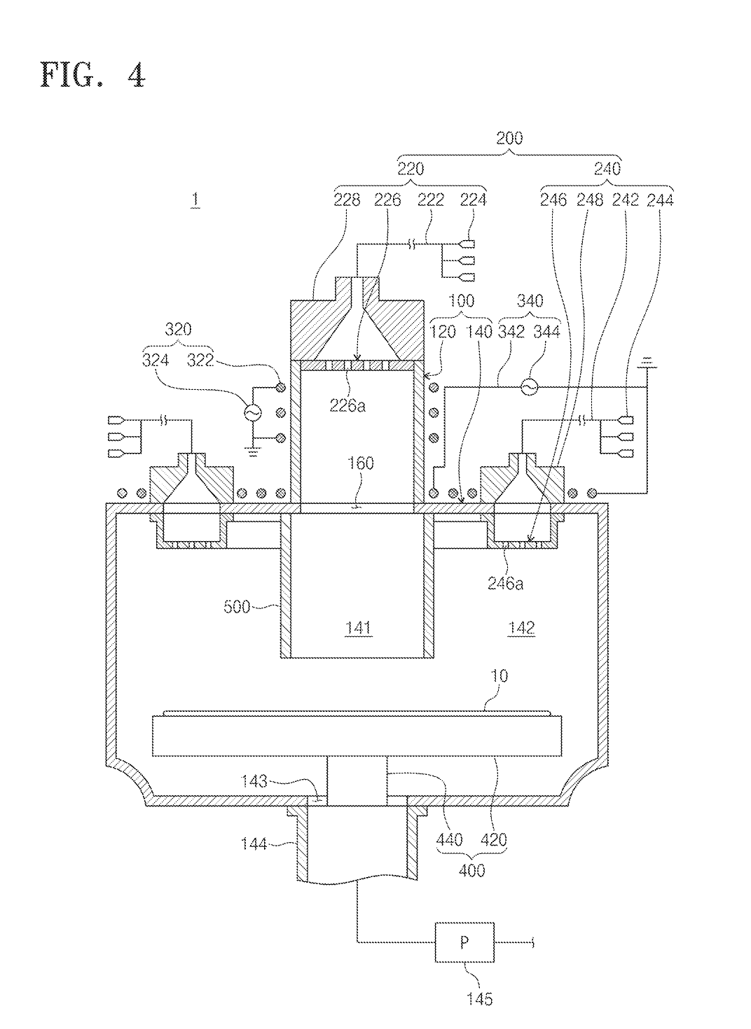

According to another embodiment of the present invention, the second source 340 may be different with that described in the previous embodiment. For instance, referring to FIG. 4, the second source 340 has the same configuration with that of the previous embodiment. However, the second antenna 342 may be disposed over the lower housing 140 to wind a circumference of the opening 160 several times.

According to another embodiment of the present invention, the substrate treating apparatus 1 may have a vortex forming surface 700. The vortex forming surface 700 may have a bellows shape or others.

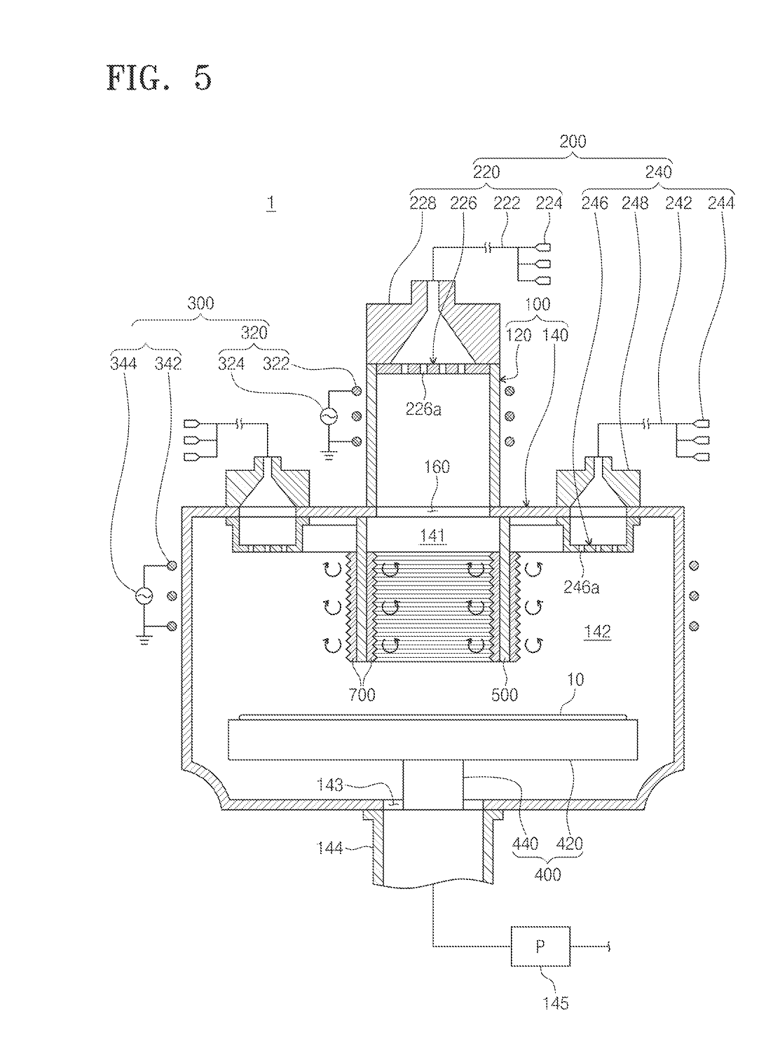

Referring to FIG. 5, the vortex forming surface 700 may be provided on inner and outer surfaces of the gas separation member 500. In this case, the vortex forming surface 700 provided on the outer surface of the gas separation member 500 generates a vortex in a flow of the second gas in the second space 142, so as to increase a retention time of the second gas in the second space 142. Accordingly, a density of plasma supplied to the edge area of the substrate 10 is increased. Also, the vortex forming surface 700 provided on the inner surface of the gas separation member 500 generates a vortex in a flow of plasma generated in the upper housing 120, thereby delaying a flow of the first gas and thus increasing a retention time of the first gas in the upper housing 120. Accordingly, a density of plasma supplied to the central area of the substrate 10 is increased.

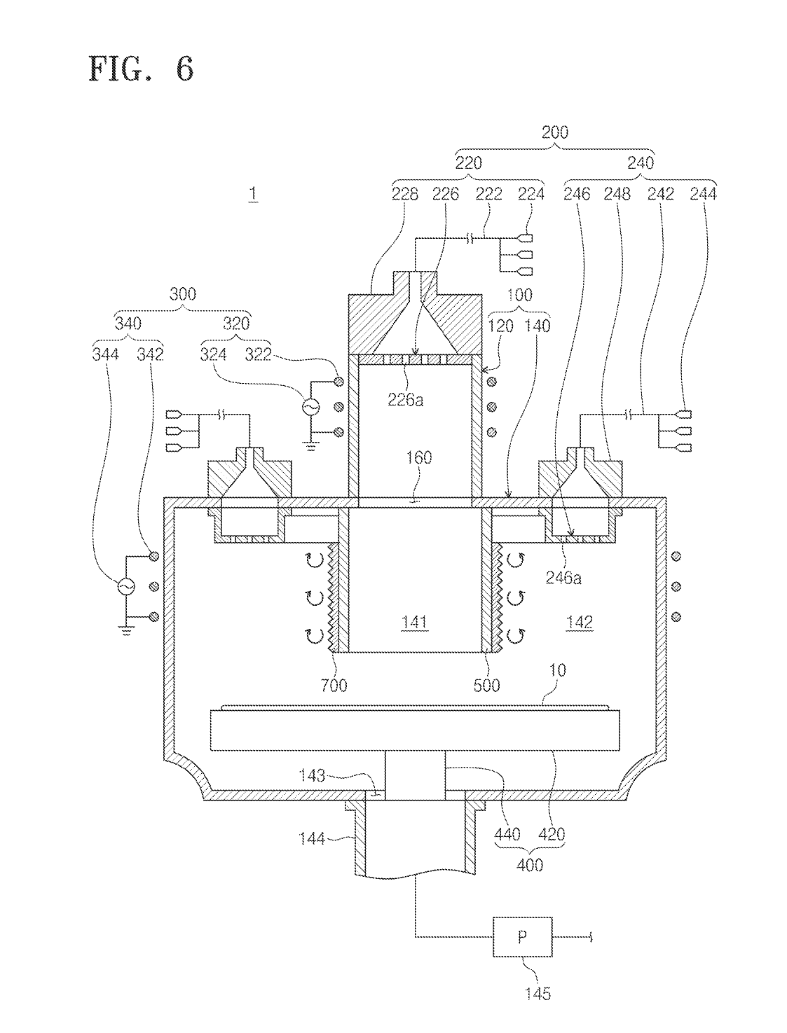

Referring to FIG. 6, the vortex forming surface 700 may be provided only on an outer surface of the gas separation member 500. In this case, the vortex forming surface 700 may have the same function as the vortex forming surface 700 provided on the outer surface of the gas separation member 500 in the FIG. 5.

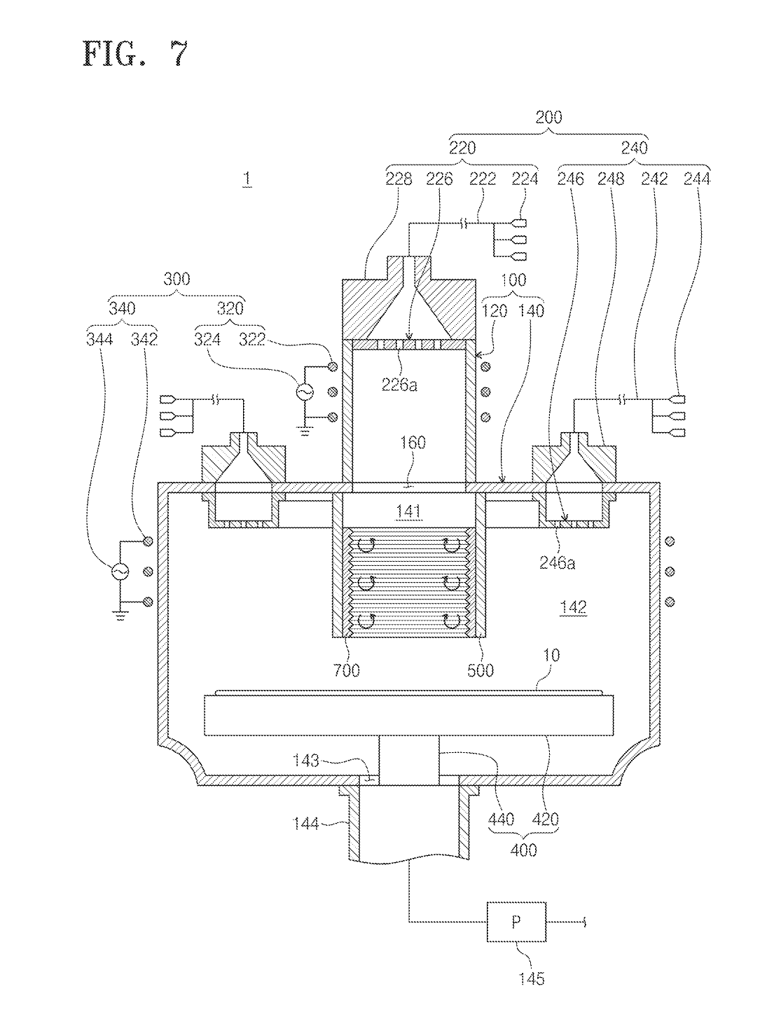

Referring to FIG. 7, the vortex forming surface 700 may be provided only on an inner surface of the gas separation member 500. In this case, the vortex forming surface 700 may have the same function with the vortex forming surface 700 provided on the inner surface of the gas separation member 500 in the FIG. 5.

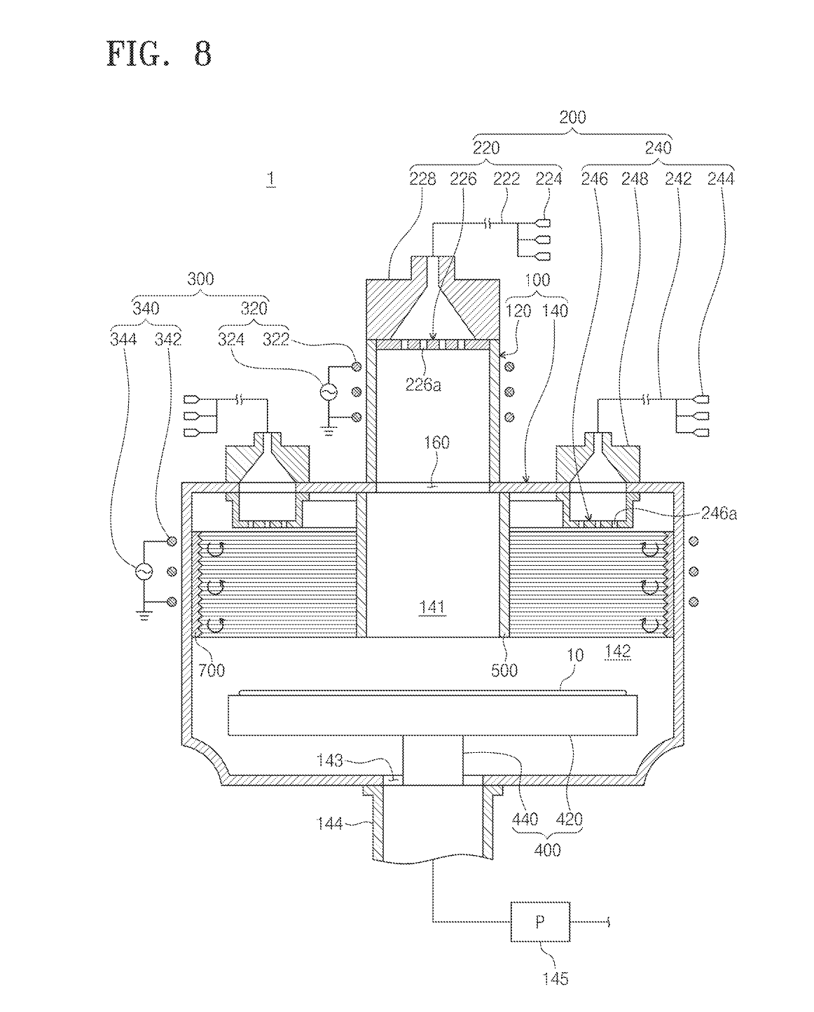

Referring to FIG. 8, the vortex forming surface 700 may be provided on an inner surface of the lower housing 140. In this case, the vortex forming surface 700 may have the same function with the vortex forming surface 700 provided on the outer surface of the gas separation member 500 in the FIG. 5.

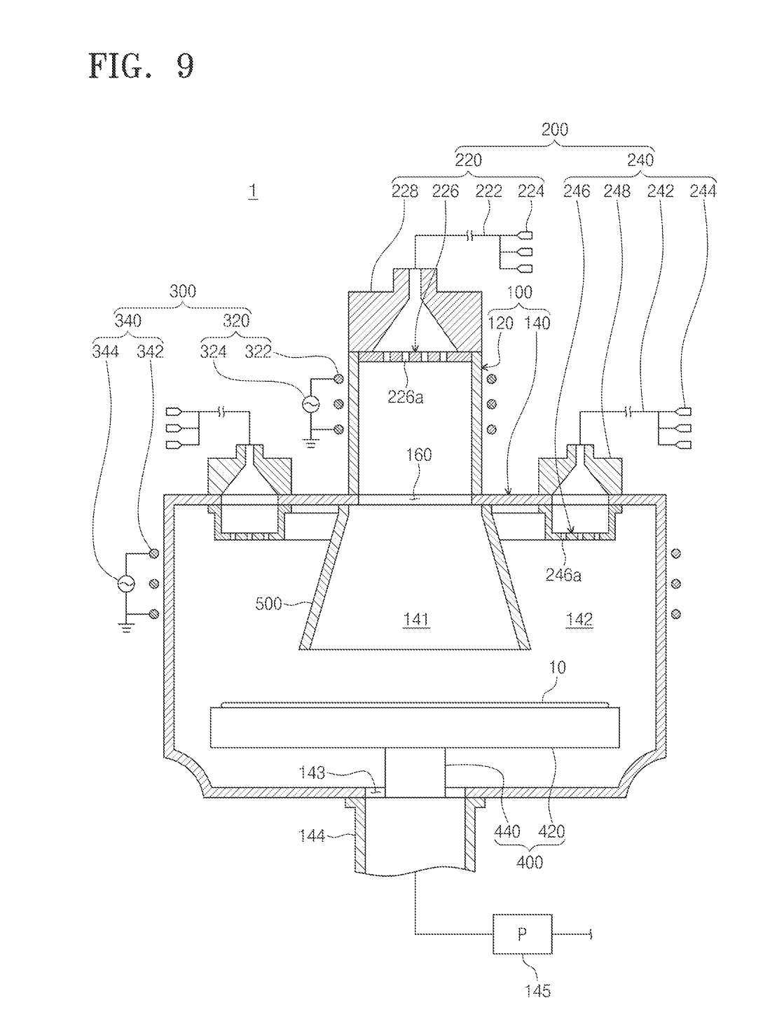

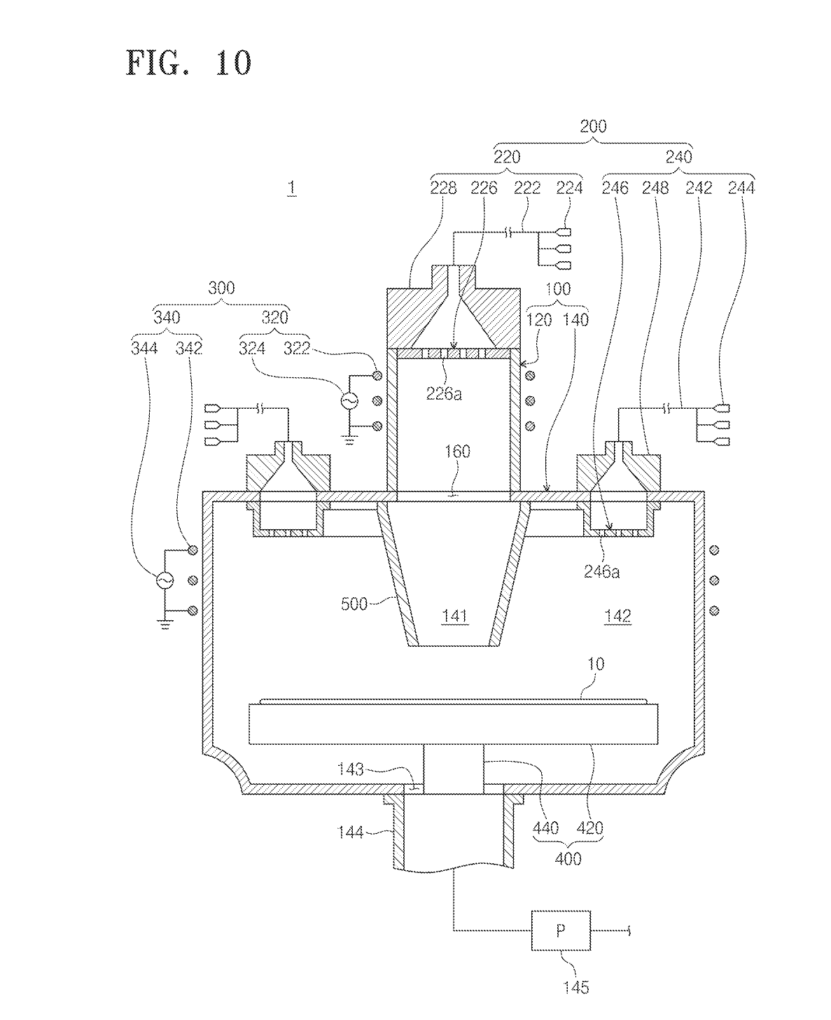

According to another embodiment of the present invention, the gas separation member 500 may have different shape with that of the substrate treating apparatus described above. For instance, referring to FIGS. 9 and 10, the gas separation member 500 may have a cylindrical shape of which a diameter gradually increases or decreases from top to bottom. The cylindrical shape may have a truncated cone shape.

A substrate treating apparatus and method according to an embodiment of the present invention may adjust each of plasma generation rates for treating central and edge areas of a substrate during a substrate treating process.

Further, a substrate treating apparatus and method according to an embodiment of the present invention may have different kinds and mixing ratios of gases injected to spaces which are opposed to central and edge areas of a substrate respectively.

The above detailed description exemplifies embodiments of the present invention. Further, the above contents just illustrate and describe preferred embodiments of the present invention and an embodiment of the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. The above-mentioned embodiments are used to describe a best mode in implementing the inventive concept. An embodiment of the present invention can be implemented in a mode other than a mode known to the art by using another invention and various modifications required a detailed application field and usage of the present invention can be made. Therefore, the detailed description of embodiments of the present invention does not intend to limit the present invention to the disclosed embodiments. Further, the appended claims should be appreciated as a step including even another embodiment.

What is claimed is:

1. A substrate treating apparatus, comprising:
a chamber comprising a lower housing and an upper housing provided on the lower housing;
a gas supplying unit supplying a gas to the chamber;
a plasma source generating plasma from the gas; and
a substrate supporting unit disposed in the lower housing to support a substrate,
wherein an opening is formed between the upper housing and the lower housing such that an inner space of the lower housing and an inner space of the upper housing are communicated with each other,
wherein the gas supplying unit comprises a first supplying unit supplying a gas into the upper housing, and a second supplying unit supplying a gas directly into the lower housing, and
wherein the plasma source comprises a first source generating plasma from the gas supplied into the upper housing, and a second source generating plasma from the gas supplied into the lower housing.

2. The substrate treating apparatus of claim 1, wherein the opening is disposed to face a central area of the substrate positioned on the substrate supporting unit.

3. The substrate treating apparatus of claim 2, wherein the second supplying unit is disposed around the opening, and is provided to supply a gas to an area facing an edge area of the substrate in the inner space of the lower housing.

4. The substrate treating apparatus of claim 2, wherein the first source winds a side surface of the upper housing.

5. The substrate treating apparatus of claim 2, wherein the second source winds a side surface of the lower housing.

6. The substrate treating apparatus of claim 2, wherein the second source is disposed over the lower housing.

7. The substrate treating apparatus of claim 1, wherein the lower housing has a vortex forming surface on an inner side thereof.

8. The substrate treating apparatus of claim 7, wherein the vortex forming surface has a bellows shape.

9. The substrate treating apparatus of claim 1, further comprising a gas separation member separating a first space from a second space, the first space facing the central area of the substrate in the inner space of the lower housing and the second space facing the edge area of the substrate,
wherein the gas separation member is disposed between first and second spaces and has an inner space with opened upper and lower ends.

10. The substrate treating apparatus of claim 9, wherein the second source is provided to wind a side surface of the lower housing and face the gas separation member.

11. The substrate treating apparatus of claim 9, wherein the gas separation member is provided with a material including nonconductive material.

12. The substrate treating apparatus of claim 11, wherein nonconductive material comprises one selected from quartz, ceramic, and sapphire.

13. The substrate treating apparatus of claim 9, wherein the gas separation member has a cylindrical shape having the same diameter vertically.

14. The substrate treating apparatus of claim 9, wherein the gas separation member has a cylindrical shape of which a diameter gradually increases from to bottom.

15. The substrate treating apparatus of claim 9, wherein the gas separation member has a cylindrical shape of which a diameter gradually decreases from top to bottom.

16. The substrate treating apparatus of claim 14, wherein the gas separation member has a truncated cone shape.

17. The substrate treating apparatus of claim 9, wherein the gas separation member has a vertex forming surface.

18. The substrate treating apparatus of claim 17, wherein the vortex forming surface is provided on an inner surface of the gas separation member.

19. The substrate treating apparatus of claim 17, wherein the vortex forming surface is provided on an outer surface of the gas separation member.

20. The substrate treating apparatus of claim 17, wherein the vortex forming surface has a bellows shape.

21. A substrate treating method using the substrate treating apparatus of claim 9, the substrate treating method comprising:
treating the central area of the substrate using plasma generated by the first source from the first gas supplied from the first supplying unit; and
treating the edge area of the substrate using plasma generated by the second source from the second gas supplied from the second supplying unit.

22. The substrate treating method of claim 21, wherein the first and second gases have different kinds.

23. The substrate treating method of claim 21, wherein the first and second gases have the same kind of gases, but have different composition ratios.

24. The substrate treating method of claim 21, wherein the first and second gases have different gas supplying amounts.
